(19) United States
(12) Patent Application Publication
(10) Pub. No.: US 2026/0299008 A1
(43) Pub. Date: Oct. 1, 2026

(54) TEST BOARD FOR CHARACTERIZING DENDRITE GROWTH IN IMMERSION-COOLING SYSTEMS

(71) Applicants: Roy ZEIGHAMI, Fall City, WA (US); Anthony SAGNERI, Dayton, NV (US); Hidekazu MIWA, Seattle, WA (US); Daniel KELLY, Kirkland, WA (US); Joshua HEMELGARN, Zurich (CH); Ethan SCHMITZ, Saint Paul, MN (US); MTS IP Holdings Ltd, George Town, Grand Cayman (KY)

(72) Inventors: Roy Zeighami, Fall City, WA (US); Anthony Sagneri, Dayton, NV (US); Hidekazu Miwa, Seattle, WA (US); Daniel Kelly, Kirkland, WA (US); Joshua Hemelgarn, Zurich (CH); Ethan Schmitz, Saint Paul, MN (US)

(21) Appl. No.: 19/490,882

(22) PCT Filed: Jun. 6, 2024
(86) PCT No.: PCT/US2024/032780

§ 371 Date: Dec. 5, 2025

Related U.S. Application Data
(60) Provisional application No. 63/506,402, filed on Jun. 6, 2023.

(51) Int. Cl. G01R 31/28; H05K 7/20

(52) U.S. Cl. CPC G01R 31/2817; H05K 7/203

(57) ABSTRACT

A test board assembly is configured to characterize dendrite formation on circuit elements exposed to immersion cooling liquid in immersion-cooling systems. The test board assembly and testing apparatus can emulate operating conditions for high-power semiconductor dies without using the semiconductor dies in the test board assembly.

### CROSS-REFERENCE TO RELATED APPLICATIONS

This application claims a priority benefit, under 35 U.S.C. § 119(e), of U.S. Application No. 63/506,402, filed on Jun. 6, 2023 titled, “Test Board for Characterizing Dendrite Growth in Two-Phase Immersion-Cooling Systems,” which application is incorporated by reference in its entirety.

### BACKGROUND

As feature sizes and transistor sizes have decreased for integrated circuits (ICs), the amount of heat generated by a single chip, such as a microprocessor, has increased. Chips that once were air cooled have evolved to chips needing more heat dissipation than can be provided by air alone. In some cases, immersion cooling of chips in a tank containing a coolant liquid is employed to maintain IC chips at appropriate operating temperatures.

One type of immersion cooling is two-phase immersion cooling, in which heat from a semiconductor die is high enough to boil the coolant liquid. The boiling creates a coolant-liquid vapor in the tank, which is condensed by cooling coils back to liquid form. Heat from the semiconductor dies can then be sunk into the liquid-to-gas and gas-to-liquid phase transitions of the coolant liquid.

Coolant liquids for immersion cooling systems can contain fluorinated compounds. During cooling, the liquid contacts exposed surfaces on printed circuit boards (PCBs) on which the IC chips and semiconductor dies are mounted. These PCBs can contain many exposed wiring traces, solder connections, and ball grid arrays (BGAs). The presence of contaminants in the coolant liquid or on the PCB can make exposed conductive elements on the PCB susceptible to undesirable dendrite formation during immersion cooling.

### SUMMARY

The present disclosure relates to a test board assembly, related apparatus, and methods for characterizing dendrite formation in two-phase immersion cooling systems, for example. The test board assembly can be used to study variables that contribute to dendrite formation in immersion cooling systems, such as single-phase and two-phase immersion cooling systems.

Some implementations relate to test board assemblies to operate in immersion coolant liquid and characterize dendrite formation during immersion cooling. An example test board assembly can comprise: a first printed circuit board (PCB) having first contacts for a ball grid array (BGA); a second PCB having second contacts for the BGA; the BGA disposed between the first PCB and the second PCB and arranged to electronically couple the first contacts on the first PCB to the second contacts on the second PCB; and at least one heating element disposed on one or both of the first PCB and the second PCB to generate heat. During operation of the test board assembly the heat generated by the at least one heating element thermally couples to at least the BGA, and the BGA is arranged on the first PCB and the second PCB to be immersed in the immersion coolant liquid.

Some implementations relate to methods for characterizing dendrite formation in immersion cooling systems with a test board assembly. The test board assembly can comprise: a first printed circuit board (PCB) having first contacts for a ball grid array (BGA); a second PCB having second contacts for the BGA; the BGA disposed between the first PCB and the second PCB and arranged to electronically couple the first contacts on the first PCB to the second contacts on the second PCB, wherein the BGA is at least partly immersed in immersion coolant liquid; and at least one heating element disposed on one or both of the first PCB and the second PCB to generate heat that couples to at least the BGA. An example method can comprise acts of: immersing at least part of the test board assembly in an immersion cooling fluid; generating heat with the at least one heating element to emulate heat generated by a semiconductor die; applying, for a period of time T, a voltage or a current to a contact of the first contacts or of the second contacts that is electrically coupled to a solder ball, a pillar, or a post of the BGA; and evaluating dendrite formation on the solder ball, the pillar, or the post as a result of applying the voltage or the current for the period of time T.

All combinations of the foregoing concepts and additional concepts discussed in greater detail below (provided such concepts are not mutually inconsistent) are part of the inventive subject matter disclosed herein. In particular, all combinations of subject matter appearing in this disclosure are part of the inventive subject matter disclosed herein. The terminology used herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally and/or structurally similar elements).

FIG. 1A depicts an example of a two-phase immersion-cooling system that can be used to cool semiconductor dies.

FIG. 1B depicts a plurality of packaged semiconductor dies mounted on a printed circuit board suitable for use in the immersion-cooling system of FIG. 1A.

FIG. 2A is a Venn diagram illustrating contaminants that contribute to dendrite formation in the two-phase immersion-cooling system of FIG. 1A.

FIG. 2B includes photographs of printed circuit board components on which dendrites have formed.

FIG. 3 illustrates (in elevation view) an example test board assembly for characterizing dendrite formation.

FIG. 4A depicts a heating element for heating a ball grid array on the test board assembly of FIG. 3.

FIG. 4B depicts detection of changes in impedance between contacts or solder balls of the ball grid array.

FIG. 5 depicts a transparent region of the test board assembly for optical access to the ball grid array.

FIG. 6 depicts an example of a testing apparatus with which to operate the test board assembly of FIG. 3.

### DETAILED DESCRIPTION

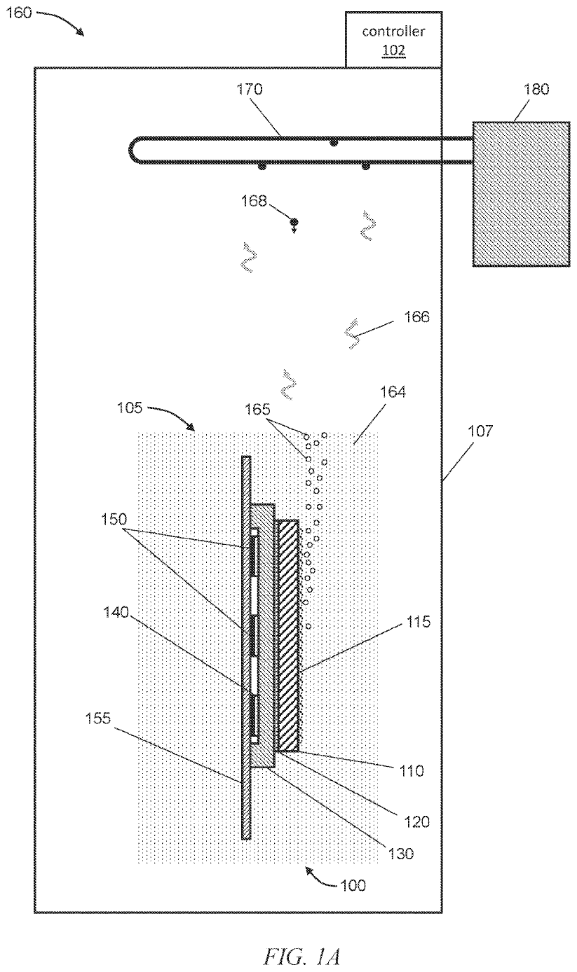

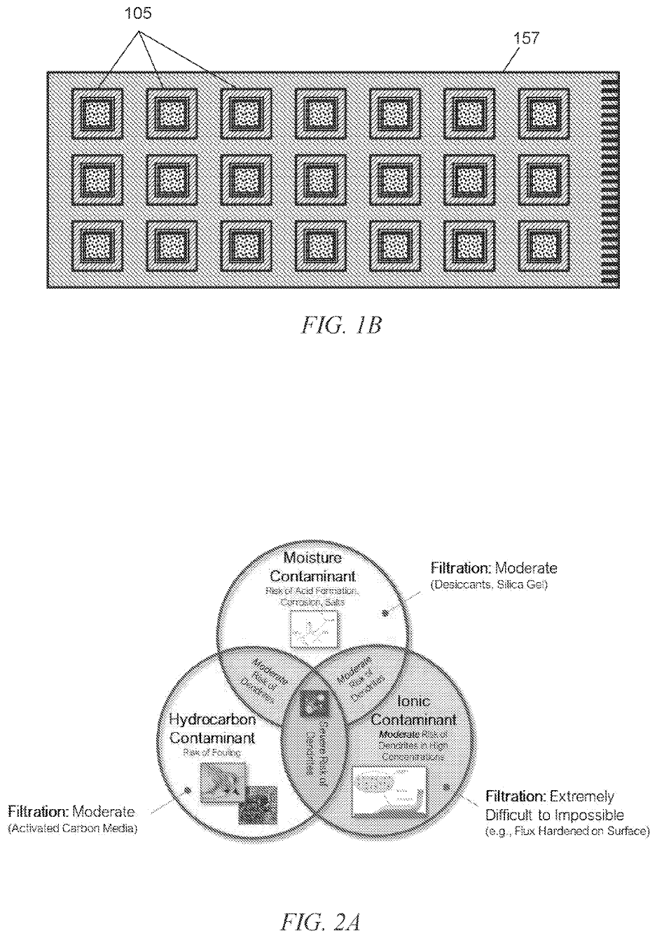

FIG. 1A depicts several features of an immersion-cooling system 160 and a cooling assembly 100 for dissipating heat from one or more semiconductor dies 150 via immersion cooling (such as two-phase or single-phase immersion cooling). The illustrated example is not to scale and depicts the cooling assembly 100 much larger in the immersion-cooling system than it would be in an actual implementation. Typically, the two-phase immersion-cooling system 160 is much larger than the cooling assembly 100. For example, the immersion-cooling system 160 may house and provide an immersion coolant liquid 164 to tens, hundreds, or even thousands of cooling assemblies 100. The cooling assemblies 100 can be mounted on one or more printed circuit boards (PCBs) that are installed within a tank 107 of the immersion-cooling system 160.

The cooling assembly 100 can include a heat spreader 110 (which may be referred to as a “boiler plate” or “heat-dissipative element” in some applications) that may thermally couple to a protective lid 130 with a first thermal interface material (TIM) 120, according to some implementations. The protective lid 130 (if present) can thermally couple to the semiconductor die(s) 150 with a second TIM 140. In some implementations, the heat spreader 110 can thermally couple directly to the semiconductor die(s) 150, as described in U.S. provisional patent application Ser. No. 63/642,432 titled “Direct to Chip Heat Spreader and Boiler Enhancement Coatings for Microelectronics,” filed May 3, 2024, and in international patent application PCT/US2023/67058 titled “Electronic Package Construction for Immersion Cooling of Integrated Circuits,” filed May 16, 2023, both of which applications are herein incorporated by reference in their entirety.

The semiconductor die(s) 150 and protective lid(s) 130 (if present) can be mounted together on, and attach to, a printed circuit board (PCB) 155 (sometimes called a “substrate”) in a device package 105 that can be made commercially available. A plurality of the device packages 105 can be populated onto a larger printed circuit board 157, as depicted in FIG. 1B. A plurality of the larger printed circuit boards 157 can be installed within the tank 107 of the immersion-cooling system 160 and cooled by the coolant liquid 164 during operation.

The cooling assembly 100 of FIG. 1A can be used for two-phase immersion cooling of at least one semiconductor die 150, such as a microprocessor (e.g., a central processing unit (CPU) and/or graphic processing unit (GPU)), voltage regulator (VR), high bandwidth memory (HBM), a digital signal processing (DSP) die, an application-specific integrated circuit (ASIC), field-programmable gate array (FPGA), and/or other densely patterned semiconductor die.

In a two-phase immersion-cooling system 160, heat flows from the semiconductor die 150 where it is generated, through the second TIM 140 (if present) into the protective lid 130 (if present), through the first TIM 120, and into the heat spreader 110. If the protective lid 130 is not used, the heat can flow from the semiconductor die 150 through the first TIM 120 and into the heat spreader 110.

The heat spreader 110 is in thermal contact with a coolant liquid 164 that can flow over and extract heat from the heat spreader 110. The amount of heat delivered by the heat spreader 110 to the coolant liquid 164 is enough to boil the coolant liquid 164 that contacts the heat spreader 110 (creating bubbles 165). The vapor 166 from the boiled coolant liquid 164 can be cooled and condensed back to liquid droplets 168, for example, by a condenser coil 170. A heat-transfer fluid, such as chilled water, from a chiller 180 can be circulated through the condenser coil 170 to condense the vapor 166 on exterior surfaces of the condenser coil 170. Liquid droplets 168 from the condensed vapor can drip and/or flow back to the coolant liquid 164 that contacts the heat spreader 110. Certain aspects of the two-phase immersion-cooling system 160 can be controlled by a controller 102, which may monitor temperatures at different points in the system and take corrective actions if overtemperatures are detected.

To improve thermal performance in two-phase immersion-cooling system 160, the heat spreader 110 can include a boiling enhancement coating (BEC) 115 on at least one surface. The BEC 115 can be formed from copper or a copper alloy and can be porous, for example, though BECs can take various forms. In some cases, the BEC 115 is a micro porous copper coating having a thickness from approximately or exactly 50 microns to 500 microns thick (which may be produced by electroplating and/or etching). In some implementations, the BEC 115 comprises a mesh copper layer bonded (e.g., via resistance heating) to at least a top surface of the heat spreader 110. In some cases, the BEC 115 is applied as particulates to at least one smooth surface of the heat spreader 110 and then subsequently sintered to adhere to one another and to the heat spreader 110. The BEC 115 provides a large surface area to contact the coolant liquid 164 and can increase the heat transfer coefficient from the heat spreader 110 to the coolant liquid 164 by up to a factor of 15 versus a smooth surface on the heat spreader 110. Accordingly, BECs 115 can increase thermal conductivity to, and accelerate the boiling of, the coolant liquid 164.

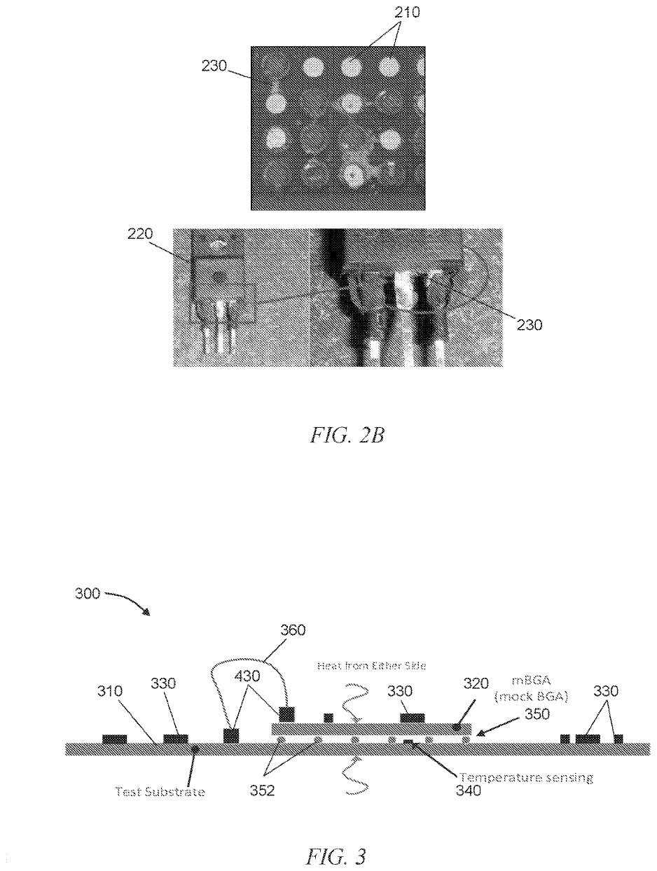

The inventors have recognized and appreciated that contaminants (e.g., water, ions, hydrocarbons) in two-phase immersion-cooling systems can cause formation of conductive dendrites on conductive elements via electrochemical migration (ECM). The conductive dendrites can cause short circuiting and failure of an integrated circuit if formed in the wrong place (e.g., across adjacent contact pads that should not be shorted to each other). The Venn diagram of FIG. 2A illustrates conditions under which conductive dendrite formation can occur and associated risk levels of dendrite formation. If both moisture (water, water vapor) and hydrocarbon contaminants are present in an immersion-cooling system, there is a moderate risk of conductive dendrite formation. There is also a moderate risk of dendrite formation if ionic contaminants are present in the system. The risk of dendrite formation increases with increasing concentration level of the contaminants. If ionic contaminants and hydrocarbon contaminants are present in the system, the risk of dendrite formation can become severe.

FIG. 2B includes photographs of PCB components (ball grid array 210 and transistor 220) on which dendrite growth 230 has occurred, forming electrical shorts between adjacent conductive elements. In an example dendrite formation process, boiling in a two-phase immersion-cooling system can distill hydrocarbon (HC) contaminants present in the coolant liquid 164 onto the ball grid array (BGA) 210. These deposited HCs can mobilize metallic ions into the coolant liquid and thereby facilitate dendrite growth by electro-chemical migration when voltages are present on the BGAs and/or other exposed electrical interconnects.

The inventors have further recognized and appreciated that dendritic growth in two-phase immersion-cooling systems has not been well characterized. Accordingly, the inventors have conceived a test board assembly and related apparatus that can be used to characterize dendrite formation in two-phase immersion-cooling systems. An example test board assembly 300 is depicted in the side-on, elevation view of FIG. 3. The test board assembly 300 can include a first PCB 310 (which may be referred to as a test substrate) and a second PCB 320 mounted on the first PCB 310. The second PCB 320 can be mounted to the first PCB 310 with at least one BGA 350 (which may be referred to as a mock BGA). For example, the first PCB 310 can have a plurality of first contacts and the second PCB 320 can have a matching plurality of second contacts. The BGA 350 can comprise solder balls, posts, or pillars 352 located between the boards to electrically couple the first contacts on the first PCB 310 to the second contacts on the second PCB 320.

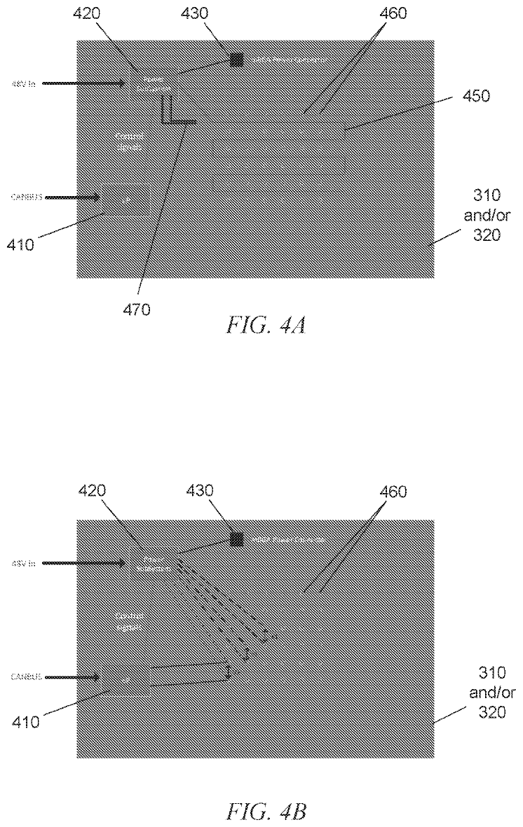

The mock BGA 350 can emulate a BGA used to mount a semiconductor die (e.g., a high-bandwidth memory or a microprocessor) to a PCB 155 and/or a BGA used to mount a device package 105 to a PCB 157 that is(are) placed in an immersion-cooling system 160 like that depicted in FIG. 1A. However, in the test board assembly 300, the BGA 350 need not establish electrical connections to a chip or semiconductor die on the first PCB 310 or second PCB 320 as it would in a commercial device package 105. Instead, the mock BGA 350 is present to emulate a BGA that can be used in a commercial device package 105. Further, at least one heating element 450 (shown in FIG. 4A) can be used to generate heat and emulate heat generation by high-power semiconductor dies that would be used, or is intended for use, in an immersion-cooling system. Of course, an actual semiconductor die can be used at higher cost. In some implementations, currents and/or voltages can be routed through and/or applied to solder balls, posts, or pillars 352 in the mock BGA 350 with circuitry patterned on the first PCB 310 and/or second PCB 320. For some tests, a voltage difference can be applied between at least two adjacent solder balls, posts, or pillars of the mock BGA 350 to establish an electric field between the adjacent balls, posts, or pillars 352.

As mentioned above, the heating element 450 can emulate operating conditions (e.g., localized heat generation) for high-power semiconductor dies that would affect the BGA 350 and nearby exposed conductive circuit elements (such as contact pads and conductive circuit traces). It can generate the greatest amount of heat and be the greatest source of heat of any component of the test board assembly (e.g., producing the highest temperature at a localized hot spot on the test board). The hot spot can be a localized area of higher temperature on the test board that is surrounded by regions of lower temperature. As such, costly semiconductor dies (such as advanced microprocessors and graphics processing units) need not be used to study dendrite formation with the test board assembly 300. Further, circuitry on the test board assembly 300 can emulate voltages, signals, and currents present at contacts and solder balls, posts, or pillars of the BGA 350 that would normally be present for a selected semiconductor die to be evaluated for dendrite formation.

There can be electronic components 330 located on one or both of the first PCB 310 and second PCB 320. The electronic components 330 can include, and are not limited to, IC devices such as analog and/or logic chips, semiconductor dies, transistors, power transistors, microprocessors, microcontrollers, field programmable gate arrays, application specific integrated circuits, sensors, heaters, etc. and discrete components such as resistors, capacitors, and inductors. Some of the electronic components 330 can be present for evaluating dendrite formation on the devices and some of the electronic components 330 can be used for operation of the test board assembly 300 (e.g., to apply the currents and/or voltages to the solder balls, posts, or pillars 352). There can be conductive traces on and/or embedded in the first PCB 310 and second PCB 320 to electrically connect different components on the PCBs. The test board assembly 300 can also include at least one interconnect cable 360 between the first PCB 310 and second PCB 320 to communicatively couple the two boards. The interconnect cable 360 can carry power and communication signals. In some implementations, the interconnect cable 360 can comprise one or more subminiature version A (SMA) cables to allow high fidelity measurements of impedance changes. In one example, parallel conductive traces for carrying high-frequency signals (e.g., in a range from 1 MHz to 5 GHz) between the first PCB 310 and second PCB 320 can connect through two solder balls 352. A high-fidelity measurement of impedance of the signal line can determine whether dendrite formation occurs along the signal line (e.g., at the exposed solder balls 352).

One or both of the first PCB 310 and second PCB 320 can include at least one temperature sensor 340 (e.g., a thermistor) to detect temperature of the first PCB 310 and/or second PCB 320 at one or more locations (e.g., within the BGA 350). The temperature sensor 340 can be used to monitor board temperature(s) during operation of the test board assembly 300. If temperatures above a threshold value are detected, then power to heating elements on the board(s) can be shut down by a controller 410 (FIG. 4A). Temperatures can also be sensed to evaluate dendrite formation as a function of operating temperature.

There can be at least one heating element 450 on one or both of the first PCB 310 and second PCB 320 to heat the board(s) and components thereon and emulate heat generation in a device package 105 and/or by components (e.g., voltage regulators, power transistors, etc.) placed on a PCB 157 that is(are) placed in an immersion-cooling system 160 like that depicted in FIG. 1A and FIG. 1B. FIG. 4A depicts a resistive heating element 450 that can be located adjacent to the BGA 350 on one or both of the first PCB 310 and second PCB 320 to heat the BGA 350. A location adjacent to the BGA 350 can be a location on either PCB 310, 320 within an area spanned by solder balls of the BGA 350 and/or within 5 millimeters of this area. If heating elements 450 are placed on both boards, they can heat the BGA 350 from both sides or from either side. The heating element(s) 450 can be used to adjust operating temperatures for test runs, (e.g., to emulate specific semiconductor dies and device packages 105 and to evaluate dendrite formation as a function of temperature).

The heating elements 450, and one or more other electronic components 330, can be controlled by at least one controller 410 (e.g., microprocessor, microcontroller, programmable logic controller, field programmable gate array, application specific integrated circuit, logic circuitry, analog circuitry, etc.) located on one or both of the first PCB 310 and second PCB 320. The first PCB 310 can include a power subsystem 420 to provide voltages and power to the electronic components 330, controller 410, BGA 350, heating element 450, and temperature sensor 340. The power subsystem 420 can also be controlled by the controller(s) 410 (e.g., to control current delivery to a heating element 450, apply voltage and/or current to the sensors 340, etc.).

The first PCB 310 and second PCB 320 can include at least one connector 430 (e.g., one or more SMA connectors, one or more mini ball grid array (mBGA) connectors, etc.) for at least one interconnect cable 360 (e.g., to couple communication signals and/or power between the PCBs). Some of the communication signals and/or applied voltages can be routed through the BGA 350. For example, signals and/or voltages can be applied by the controller 410 to contacts 460 on the first PCB 310 for the BGA 350, received at corresponding contacts on the second PCB 320 for the BGA 350, and routed back through the interconnect cable(s) 360 to the controller 410 for evaluation. Alternatively, the signals and power may be applied first to the interconnect cable(s) 360 and routed back through the BGA 350.

The power subsystem 420 can be communicatively coupled to and controlled by the controller 410. The power subsystem 420 can also electronically couple to one or more contacts 460 for the BGA 350 via traces on the PCB. For example, the controller 410 can issue commands to apply different values of voltages (e.g., in a range from 0.1 volt to 100 volts) to at least some of the contacts 460 and connected BGA 350. Advantageously, voltages and/or current can be applied by the controller 410 to the contacts 460 of the BGA 350 independently from one another, as depicted in FIG. 4B. For example, the controller 410 can apply any selected voltage between any two contacts 460 of the BGA 350. By applying higher voltages and/or higher power levels than would be used in normal operating conditions for a PCB 155 of a device package 105 and/or the larger PCB 157, the test board assembly 300 can be used for accelerated testing of PCB configurations immersed in a coolant liquid environment. The controller 410 can also electronically couple to one or more contacts 460 for the BGA 350 via traces on the PCB and apply signals to the one or more contacts 460. In this manner, the test board assembly 300 can emulate typical power and signaling supported by the BGA 350 that would occur in a device package 105 and/or on a PCB 157 that is placed in an immersion-cooling system 160 like that depicted in FIG. 1A and FIG. 1B.

The first PCB 310 and/or second PCB 320 can also include at least one pair of conductive traces 470 for measuring surface insulation resistance. Surface insulation resistance can be measured at or near the BGA 350 and/or at other locations on the boards.

FIG. 4B illustrates that shorts and/or changes in impedance between contacts 460 of the BGA 350 can be detected with the test board assembly 300. For example, the controller 410 can be configured to sense a voltage difference and/or impedance (V3 in the illustrated example) between two contacts when a voltage or current is applied across the contacts by the power subsystem 420. Shorts and/or changes in impedance can be due to dendrite formation. Thus, the test board assembly 300 can monitor for dendrite formation in real time. In some implementations, the shorts and/or changes in impedance can be detected by the power subsystem 420 and/or controller 410. One or both of the power subsystem 420 and controller 410 can include circuitry to detect impedance changes and/or shorts between contacts 460. When a short or low impedance (below a threshold value) is detected, the controller 410 can shut down voltages and power or limit current to at least the affected contacts in order to prevent board damage. Changes in impedance, shorts, and other information from the test board assembly 300 can be communicated to another remote processor via a data link (such as a CANBUS link). The other processor may be located in a system controller, which could be a personal computer for example.

FIG. 5 depicts a portion of a PCB 500 that is transparent. For example, the PCB 500 can comprise a transparent material 510 (e.g., a polymer such as polycarbonate or an acrylic polymer) or a ceramic (such as alumina). In some implementations, the transparent material can be a glass, such as fused silica or quartz. A transparent PCB 500 can allow optical observation of dendrite formation around contacts 460, exposed conductive traces, and/or solder balls of the BGA 350 during operation of the test board assembly 300. The conductive circuit traces 520 may or may not be covered by a protective layer (such as a thin layer of resist or another polymer). In some cases, the protective layer can cover most conductive traces but be removed from an area 540 to provide exposed conductive traces 522, 524 for studying dendrite formation between exposed traces. The exposed conductive traces 522, 524 can extend adjacent to each other for a distance on the same printed circuit board. The test board assembly 300 can be configured to apply a voltage and/or current to at least one of the exposed conductive traces 522, 524 (e.g., such that an electric field can form between the exposed conductive traces 522, 524 and/or around at least one of the traces). In some cases, the exposed conductive traces 522, 524 can be located at a region of the printed circuit board such that heat from a heating element 450 disposed on the printed circuit board can thermally couple to the exposed conductive traces 522, 524 and heat them to a desired temperature. A temperature sensor 340 can be disposed adjacent to the exposed conductive traces 522, 524 to measure the local temperature. In some implementations, the transparent PCB 500 can be used for the second PCB 320 of the test board assembly 300. The transparent PCB 500 can be used additionally or alternative for the first PCB 310 in some implementations.

The test board assembly 300 can be used to characterize dendrite formation at low cost (e.g., less than $1000 per test board assembly) and at low power levels (e.g., on the order of 10′s of watts). The test board assembly 300 can provide tight control and monitoring of several variables that contribute to dendrite formation, so that each of their effects on dendrite formation can be evaluated. Such variables include, but are not limited to, amount of solder flux residue remaining on board when placed in operation, board cleaning protocols (which can affect the amount of flux residue), type and quality of coolant liquid 164, fluid contamination levels, voltage and power levels applied to contacts, exposed traces, and solder balls, posts, or pillars, and heat loading on the PCBs. As noted above, with the ability to control voltages on the PCBs, the test board assembly 300 can provide accelerated testing of PCB designs.

In one example, flux residue on a test board assembly 300 can be varied over a sequence of test runs to evaluate the effect of flux residue levels on dendrite formation. Each test run can comprise operating the test board assembly 300 over a fixed period of time T (which could be any amount of time in a range from minutes to days) and quantifying an amount of dendrite formation on exposed conductive elements on the test board assembly 300 for a given flux residue level on the tested printed circuit boards. Flux residue can be measured at the beginning of each test run and may be expressed as a quantity per unit surface area of the tested PCBs (e.g., micrograms/cm² or any other suitable measure). Results from the sequence of tests can be analyzed to determine dendrite growth rate as a function of flux residue level and in response to applied voltages and/or currents.

In another example, concentration(s) of fluid contaminants can be varied over a sequence of test runs to evaluate the effect of contaminant concentration levels on dendrite formation. Each test run can comprise operating the test board assembly 300 over a fixed period of time T (which could be any amount of time in a range from minutes to days) and quantifying an amount of dendrite formation on exposed conductive elements on the test board assembly 300 for a given contamination level of one or more contaminants in the coolant liquid. Fluid contamination levels can be controlled by adding one or more contaminants (hydrocarbons, water, metal ions) to the coolant liquid prior to each test run to reach a desired concentration level of each added contaminant. Results from the sequence of tests can be analyzed to determine dendrite growth rate as a function of fluid contaminant level or concentration and in response to applied voltages and/or currents.

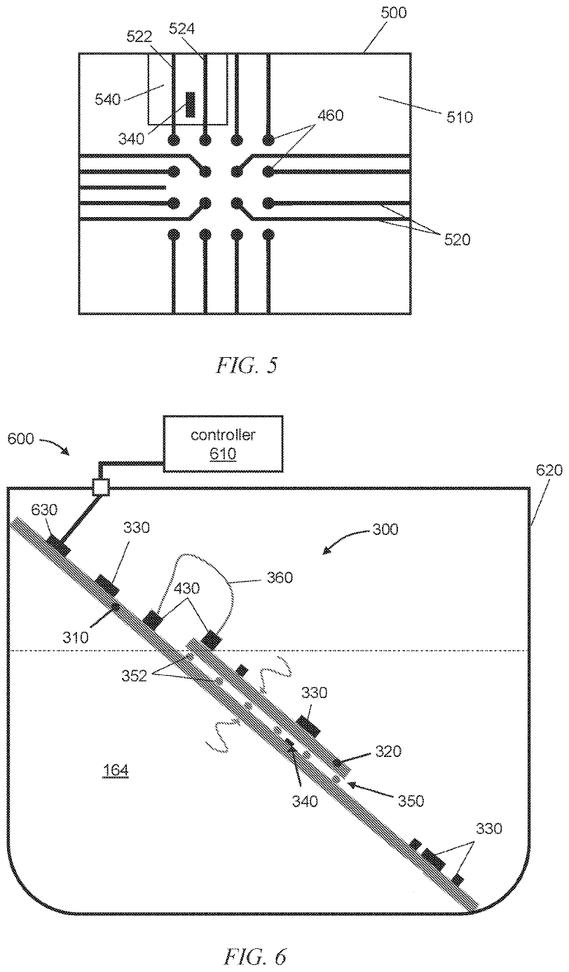

FIG. 6 depicts an example of testing apparatus 600 for operating the test board assembly 300 during test runs. The testing apparatus 600 comprises a test tank 620 that contains immersion coolant liquid 164 and the test board assembly 300. The test tank 620 can be sealed or unsealed. In some implementations, the test tank 620 is sealed and the testing apparatus further comprises at least one condenser coil disposed in the test tank 620 and a chiller to circulate heat-transfer fluid through the condensing coil, like the arrangement of the condenser coil 170 and chiller 180 in FIG. 1A. A remote processor 610 can be communicatively coupled (via a wired and/or wireless link) to the test board assembly 300 to control operation of and/or receive data from the test board assembly 300. The test board assembly 300 can include a connector and/or wireless port 630 for the wired and/or wireless link to the remote processor. A wireless port 630 can comprise an RF transceiver chip, for example. The remote processor 610 can be implemented as a microcontroller, microprocessor, programmable logic controller, field programmable gate array, application specific integrated circuit, digital logic circuitry, analog circuitry, or some combination thereof.

According to some implementations, at least some connectors 430 and cabling 360 are arranged on the test board assembly 300 and the test board assembly 300 is arranged in the test tank 620 such that the connectors 430 and cabling 360 are not immersed in the coolant liquid 164, as depicted in FIG. 6. The level of the coolant liquid is indicated by the dashed line. However, the BGA 350 under test is immersed in the coolant liquid as it would be under normal operation in an immersion cooling system. Also, at least portions of the first PCB 310 and second PCB 320 at which heat is generated are also immersed in the coolant liquid 164, as they would be under normal operation in an immersion cooling system. Keeping the connectors 430 and cabling 360 out of the coolant liquid can avoid contaminants from these components entering into the coolant liquid 164 during test runs and undesirably affecting test results (e.g., varying the contaminant level and or type in the coolant liquid 164 during each test run).

The above described test board assemblies and methods can be implemented in various ways. Some example implementations are listed below.
(1) A test board assembly to operate in immersion coolant liquid and characterize dendrite formation during immersion cooling, the test board assembly comprising: a first printed circuit board (PCB) having first contacts for a ball grid array (BGA); a second PCB having second contacts for the BGA; the BGA disposed between the first PCB and the second PCB and arranged to electronically couple the first contacts on the first PCB to the second contacts on the second PCB; and at least one heating element disposed on one or both of the first PCB and the second PCB to generate heat. During operation of the test board assembly: the heat generated by the at least one heating element thermally can couple to at least the BGA, and the BGA can be arranged on the first PCB and the second PCB to be immersed in the immersion coolant liquid.
(2) The test board assembly of configuration (1), wherein during operation of the test board assembly: the at least one heating element is the greatest source of heat generated by any component of the test board assembly; and the at least one heating element produces a localized hot spot on the test board assembly comprising a first region of the test board assembly having a first temperature that is higher than temperatures of regions of the test board assembly surrounding the first region and higher than any other temperature measured on the test board assembly.
(3) The test board assembly of configuration (2), wherein the at least one heating element is configured to emulate heat generation by a semiconductor die.
(4) The test board assembly of any one of configurations (1) through (3), further comprising circuitry and at least one controller to detect a short circuit condition or a change in impedance between at least two contacts of the first contacts, at least two contacts of the second contacts, or at least two solder balls of the BGA when the test board assembly is operating and at least partly immersed in the immersion coolant liquid.
(5) The test board assembly of configuration (4), wherein the at least one controller is mounted on the first PCB or the second PCB and is configured to limit current to the at least two contacts of the first contacts, the at least two contacts of the second contacts, or the at least two solder balls of the BGA in response to detecting the short circuit condition or the change in impedance.
(6) The test board assembly of configuration (4) or (5), further comprising: a power subsystem located on the first PCB or the second PCB and communicatively coupled to the at least one controller, wherein the at least one controller is configured to operate the power subsystem to apply a selected voltage from among a plurality of voltage values between the at least two contacts of the first contacts or the at least two contacts of the second contacts.
(7) The test board assembly of any one of configurations (1) through (6), further comprising a temperature sensor to detect a temperature of a first region of the first PCB adjacent to the BGA or of a second region of the second PCB adjacent to the BGA.
(8) The test board assembly of any one of configurations (1) through (7), further comprising: a first connector on the first PCB; a second connector on the second PCB; and an interconnect cable connected between the first connector and the second connector.
(9) The test board assembly of configuration (8), wherein the first connector comprises a mini ball grid array connector.
(10) The test board assembly of configuration (8) or (9), wherein the first connector, the second connector, and the interconnect cable are arranged on the first PCB and the second PCB such that they are not immersed in the immersion coolant liquid when the test board assembly is operating and at least partly immersed in the immersion coolant liquid.
(11) The test board assembly of any one of configurations (1) through (10), further comprising: a transparent region of the first PCB or the second PCB adjacent to the BGA to allow optical viewing of the BGA during operation of the test board assembly.
(12) The test board assembly of configuration (11), wherein the transparent region comprises a polymer or a ceramic.
(13) The test board assembly of configuration (12), wherein the polymer is polycarbonate.
(14) The test board assembly of configuration (12), wherein the polymer is an acrylic polymer.
(15) The test board assembly of configuration (12), wherein the ceramic is alumina.
(16) The test board assembly of any one of configurations (1) through (15), in combination with a test tank in which to at least partly immerse the test board assembly in the immersion coolant liquid.
(17) The test board assembly of any one of configurations (1) through (16), further comprising at least one connector to communicatively couple to a remote processor.
(18) The test board assembly of any one of configurations (1) through (16), further comprising at least one wireless port to communicatively couple to a remote processor.
(19) The test board assembly of any one of configurations (1) through (18), wherein the first PCB or the second PCB comprises at least one semiconductor die.
(20) The test board assembly of any one of configurations (1) through (19), wherein the first PCB or the second PCB comprises at least one power transistor.
(21) The test board assembly of any one of configurations (1) through (20), wherein the first PCB or the second PCB comprises: a first conductive circuit trace arranged to be exposed to the immersion coolant liquid when the test board assembly is operating and at least partly immersed in the immersion coolant liquid; and a second conductive circuit trace arranged to be exposed to the immersion coolant liquid when the test board assembly is operating and at least partly immersed in the immersion coolant liquid. The second conductive circuit trace extends adjacent to the first conductive circuit trace on the same printed circuit board as the first conductive circuit trace and the test board assembly is configured to apply a voltage to at least one of the first conductive circuit trace and the second conductive circuit trace.
(22) The test board assembly of configuration (21), wherein the first conductive circuit trace and the second conductive circuit trace are located on the first PCB or the second PCB such that heat from the at least one heating element thermally couples to the first conductive circuit trace and the second conductive circuit trace.

The following methods may be used when operating an implementation of the test board assembly, such as an implementation according to one of the above-listed configurations.
(23) A method for characterizing dendrite formation in immersion cooling systems with a test board assembly. The test board assembly can comprise: a first printed circuit board (PCB) having first contacts for a ball grid array (BGA); a second PCB having second contacts for the BGA; the BGA disposed between the first PCB and the second PCB and arranged to electronically couple the first contacts on the first PCB to the second contacts on the second PCB, wherein the BGA is at least partly immersed in immersion coolant liquid; and at least one heating element disposed on one or both of the first PCB and the second PCB to generate heat that couples to at least the BGA. The method for characterizing dendrite formation can comprise acts of: immersing at least part of the test board assembly in an immersion cooling fluid; generating heat with the at least one heating element to emulate heat generated by a semiconductor die; applying, for a period of time T, a voltage or a current to a contact of the first contacts or of the second contacts that is electrically coupled to a solder ball, a pillar, or a post of the BGA; and evaluating dendrite formation on the solder ball, the pillar, or the post as a result of applying the voltage or the current for the period of time T.
(24) The method of (23), wherein the voltage has a value up to 100 volts.
(25) The method of (23) or (24), wherein the voltage or the current is a higher value than would normally be applied to the solder ball, the pillar, or the post and thereby comprises accelerated testing of the test board assembly.
(26) The method of any one of (23) through (25), wherein; the at least one heating element generates the greatest amount of heat generated by any component of the test board assembly; and the at least one heating element produces a localized hot spot on the test board assembly comprising a first region of the test board assembly having a first temperature that is higher than temperatures of regions of the test board assembly surrounding the first region and higher than any other temperature measured on the test board assembly.
(27) The method of any one of (23) through (26), further comprising: operating, with a controller, a power subsystem to apply a selected voltage from among a plurality of voltage values between at least two contacts of the first contacts or at least two contacts of the second contacts.
(28) The method of (27), further comprising: detecting, with the controller, a short circuit condition or a change in impedance between the at least two contacts of the first contacts, the at least two contacts of the second contacts, or at least two solder balls of the BGA.
(29) The method of (28), further comprising: limiting current, by the controller, to the at least two contacts of the first contacts or the at least two contacts of the second contacts in response to detecting the short circuit condition or change in impedance.
(30) The method of any one of (23) through (29), further comprising: detecting, with a temperature sensor, a temperature of a first region of the first PCB adjacent to the BGA or of a second region of the second PCB adjacent to the BGA.
(31) The method of any one of (23) through (30), further comprising:
   coupling signals and/or power between the first PCB and the second PCB with at least one interconnect cable connected between a first connector disposed on the first PCB and a second connector disposed on the second PCB.
(32) The method of (31), wherein the first connector, the second connector, and the interconnect cable are not immersed in the immersion coolant liquid.
(33) The method of any one of (23) through (32), further comprising: viewing the BGA for formation of dendrites during operation of the test board assembly.
(34) The method of any one of (23) through (33), further comprising: adding at least one contaminant to the immersion coolant liquid prior to applying the voltage or the current, the at least one contaminant added to obtain a desired concentration of the at least one contaminant in the immersion coolant liquid.
(35) The method of (34), wherein the at least one contaminant comprises a hydrocarbon.
(36) The method of (34), wherein the at least one contaminant comprises water.
(37) The method of (34), wherein the at least one contaminant comprises a metal ion.
(38) The method of any one of (23) through (37), further comprising communicatively coupling information from the test board assembly to a remote processor.
(39) The method of any one of (23) through (38), wherein the voltage is a first voltage and the current is a first current, the method further comprising acts of: applying a second voltage or a second current for the period of time T to a first conductive trace on the first PCB or on the second PCB; and evaluating dendrite formation on the first conductive trace as a result of applying the second voltage or the second current for the period of time T, wherein: the first conductive trace is exposed to the immersion coolant liquid and extends adjacent to a second conductive trace for a distance; the second conductive trace is located on the same PCB as the first conductive trace; and the second conductive trace is exposed to the immersion coolant liquid along the distance.
(40) The method of (39), further comprising: heating the first conductive trace and the second conductive trace with the at least one heating element.
(41) The method of (40), further comprising: detecting, with a temperature sensor, a temperature of a region of the first PCB or the second PCB containing the first conductive trace and the second conductive trace.

### Conclusion

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that inventive embodiments may be practiced otherwise than as specifically described. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

Unless stated otherwise, the terms “approximately” and “about” are used to mean within ±20% of a target (e.g., dimension or orientation) in some embodiments, within ±10% of a target in some embodiments, within ±5% of a target in some embodiments, and yet within ±2% of a target in some embodiments. The terms “approximately” and “about” can include the target. The term “essentially” is used to mean within ±3% of a target.

The indefinite articles “a” and “an,” as used herein, unless clearly indicated to the contrary, should be understood to mean “at least one.”

The phrase “and/or,” as used herein, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of” or “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” shall have its ordinary meaning as used in the field of patent law.

As used herein, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1-22. (canceled)

23. A method for characterizing dendrite formation in immersion cooling systems with a test board assembly, the method comprising:
immersing at least part of the test board assembly in an immersion cooling fluid, the test board assembly comprising:
a first printed circuit board (PCB) having first contacts for a ball grid array (BGA);
a second PCB having second contacts for the BGA;
the BGA disposed between the first PCB and the second PCB and arranged to electronically couple the first contacts on the first PCB to the second contacts on the second PCB, wherein the BGA is at least partly immersed in immersion coolant liquid; and
at least one heating element disposed on one or both of the first PCB and the second PCB to generate heat that couples to at least the BGA;
generating heat with the at least one heating element to emulate heat generated by a semiconductor die;
applying, for a period of time T, a voltage or a current to a contact of the first contacts or of the second contacts that is electrically coupled to a solder ball, a pillar, or a post of the BGA; and
evaluating dendrite formation on the solder ball, the pillar, or the post as a result of applying the voltage or the current for the period of time T.

24. The method of claim 23, wherein the voltage has a value up to 100 volts.

25. The method of claim 24, wherein the voltage or the current is a higher value than would normally be applied to the solder ball, the pillar, or the post and thereby comprises accelerated testing of the test board assembly.

26. The method of claim 23, wherein;
the at least one heating element generates the greatest amount of heat generated by any component of the test board assembly; and
the at least one heating element produces a localized hot spot on the test board assembly comprising a first region of the test board assembly having a first temperature that is higher than temperatures of regions of the test board assembly surrounding the first region and higher than any other temperature measured on the test board assembly.

27. The method of claim 23, further comprising:
operating, with a controller, a power subsystem to apply a selected voltage from among a plurality of voltage values between at least two contacts of the first contacts or at least two contacts of the second contacts.

28. The method of claim 27, further comprising:
detecting, with the controller, a short circuit condition or a change in impedance between the at least two contacts of the first contacts, the at least two contacts of the second contacts, or at least two solder balls of the BGA.

29. The method of claim 28, further comprising:
limiting current, by the controller, to the at least two contacts of the first contacts or the at least two contacts of the second contacts in response to detecting the short circuit condition or change in impedance.

30. The method of claim 23, further comprising:
detecting, with a temperature sensor, a temperature of a first region of the first PCB adjacent to the BGA or of a second region of the second PCB adjacent to the BGA.

31. The method of claim 23, further comprising:
coupling signals and/or power between the first PCB and the second PCB with at least one interconnect cable connected between a first connector disposed on the first PCB and a second connector disposed on the second PCB.

32. The method of claim 31, wherein the first connector, the second connector, and the interconnect cable are not immersed in the immersion coolant liquid.

33. The method of claim 23, further comprising:
viewing the BGA for formation of dendrites during operation of the test board assembly.

34. The method of claim 23, further comprising:
adding at least one contaminant to the immersion coolant liquid prior to applying the voltage or the current, the at least one contaminant added to obtain a desired concentration of the at least one contaminant in the immersion coolant liquid.

35. The method of claim 34, wherein the at least one contaminant comprises a hydrocarbon.

36. The method of claim 34, wherein the at least one contaminant comprises water.

37. The method of claim 34, wherein the at least one contaminant comprises a metal ion.

38. The method of claim 23, further comprising communicatively coupling information from the test board assembly to a remote processor.

39. The method of claim 23, wherein the voltage is a first voltage and the current is a first current, the method further comprising:
applying a second voltage or a second current for the period of time T to a first conductive trace on the first PCB or on the second PCB, wherein:
the first conductive trace is exposed to the immersion coolant liquid and extends adjacent to a second conductive trace for a distance;
the second conductive trace is located on the same PCB as the first conductive trace; and
the second conductive trace is exposed to the immersion coolant liquid along the distance; and
evaluating dendrite formation on the first conductive trace as a result of applying the second voltage or the second current for the period of time T.

40. The method of claim 39, further comprising:
heating the first conductive trace and the second conductive trace with the at least one heating element.

41. The method of claim 40, further comprising:
detecting, with a temperature sensor, a temperature of a region of the first PCB or the second PCB containing the first conductive trace and the second conductive trace.
